(19) United States
(12) Patent Application Publication
(10) Pub. No.: US 2026/0293086 A1
(43) Pub. Date: Sep. 24, 2026

(54) METHOD OF MANUFACTURING SEMICONDUCTOR DEVICE

(71) Applicant: Kioxia Corporation, Tokyo (JP)

(72) Inventors: Tomoharu OKADA, Yokkaichi Mie (JP); Yusuke KASAHARA, Yokkaichi Mie (JP)

(73) Assignee: Kioxia Corporation, Tokyo (JP)

(21) Appl. No.: 19/268,781

(22) Filed: Jul. 14, 2025

(30) Foreign Application Priority Data
Mar. 18, 2025 (JP) 2025-043849

(51) Int. Cl. H10B 12/00; H10D 30/01; H10W 20/00

(52) U.S. Cl. CPC H10B 12/01; H10D 30/0318; H10W 20/031

(57) ABSTRACT

In one embodiment, a method of manufacturing a semiconductor device includes forming a conductive layer including a metal element and oxygen, and forming a first film on the conductive layer. The device further includes forming a concave portion in the first film, and forming a second film in the concave portion. The device further includes etching the second film in the concave portion using a first gas including Cl (chloride) to expose a surface of the conductive layer in the concave portion. The device further includes oxidizing the surface of the conductive layer exposed in the concave portion, and forming a semiconductor layer in the concave portion such that the semiconductor layer contacts the oxidized surface of the conductive layer.

### CROSS REFERENCE TO RELATED APPLICATION

This application is based upon and claims the benefit of priority from the prior Japanese Patent Application No. 2025-043849, filed on Mar. 18, 2025, the entire contents of which are incorporated herein by reference.

### FIELD

Embodiments described herein relate to a method of manufacturing a semiconductor device.

### BACKGROUND

When a film on a conductive layer is etched by dry etching, an element derived from an etching gas may react with the conductive layer exposed from the film, resulting in an increase in electrical resistance of the conductive layer.

### BRIEF DESCRIPTION OF THE DRAWINGS

FIG. 1 is a circuit diagram illustrating a configuration of a semiconductor device of a first embodiment;

FIG. 2 is a cross-sectional view illustrating a structure of the semiconductor device of the first embodiment;

FIGS. 3-6 are cross-sectional views illustrating a method of manufacturing the semiconductor device of the first embodiment;

FIGS. 7A-8B are cross-sectional views illustrating the method of manufacturing the semiconductor device of the first embodiment;

FIGS. 9A and 9B are cross-sectional views illustrating a method of manufacturing a semiconductor device of a comparative example of the first embodiment;

FIGS. 10A-11B are cross-sectional views illustrating the method of manufacturing the semiconductor device of the first embodiment;

FIGS. 12A-13B are cross-sectional views illustrating a method of manufacturing a semiconductor device of a second embodiment; and

FIGS. 14A-15B are cross-sectional views illustrating a method of manufacturing the semiconductor device of the second embodiment.

### DETAILED DESCRIPTION

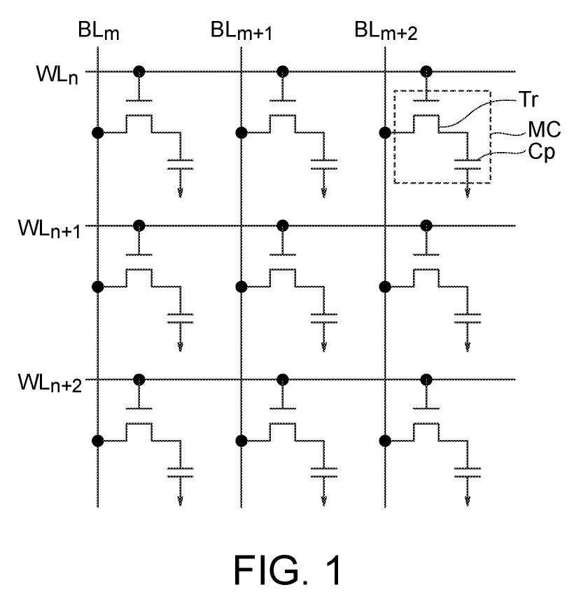

Embodiments will now be explained with reference to the accompanying drawings. In FIGS. 1-15B, same components are denoted by the same reference numerals, and duplicated description thereof will be omitted.

In one embodiment, a method of manufacturing a semiconductor device includes forming a conductive layer including a metal element and oxygen, and forming a first film on the conductive layer. The device further includes forming a concave portion in the first film, and forming a second film in the concave portion. The device further includes etching the second film in the concave portion using a first gas including Cl (chloride) to expose a surface of the conductive layer in the concave portion. The device further includes oxidizing the surface of the conductive layer exposed in the concave portion, and forming a semiconductor layer in the concave portion such that the semiconductor layer contacts the oxidized surface of the conductive layer.

### First Embodiment

FIG. 1 is a circuit diagram illustrating a configuration of a semiconductor device of a first embodiment. The semiconductor device of the present embodiment is, for example, a dynamic random access memory (DRAM).

The semiconductor device of the present embodiment includes a plurality of word lines WL extending in a row direction, a plurality of bit lines BL extending in a column direction, and a plurality of memory cells MC disposed in a two-dimensional array. FIG. 1 illustrates three word lines WLₙ, WLₙ₊₁, and WLₙ₊₂ (n being an integer of two or greater) as examples of the plurality of word lines WL. FIG. 1 further illustrates three bit lines BLₘ, BLₘ₊₁, and BLₘ₊₂(m being an integer of two or greater) as examples of the plurality of bit lines BL.

Each memory cell MC includes a transistor Tr and a capacitor Cp, and is disposed near an intersection point of one word line WL and one bit line BL. The gate of the transistor Tr is electrically connected to the word line WL, one of the source and drain of the transistor Tr is electrically connected to the bit line BL, and the other of the source and drain of the transistor Tr is electrically connected to the capacitor Cp. One of the electrodes of the capacitor Cp is electrically connected to the transistor Tr, and the other electrode of the capacitor Cp is electrically connected to a ground line.

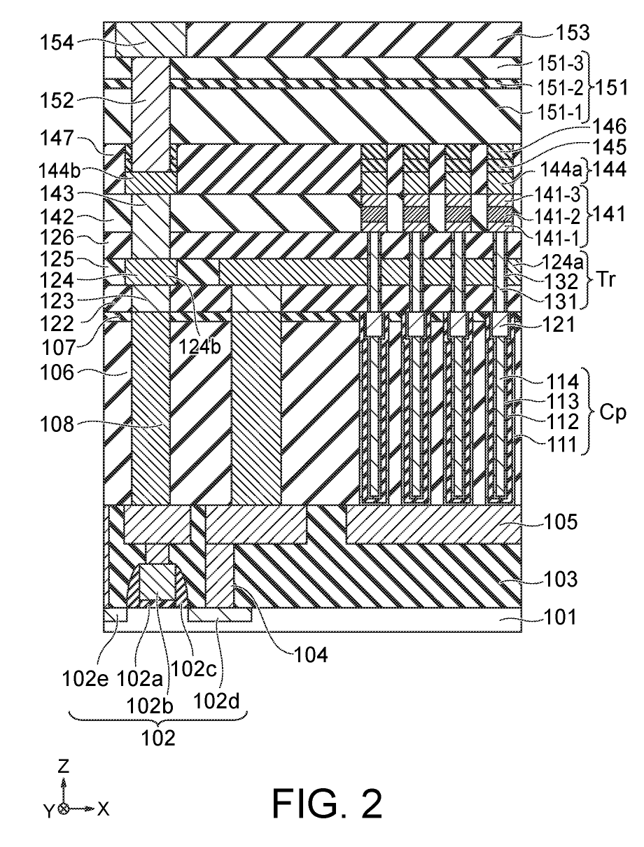

FIG. 2 is a cross-sectional view illustrating a structure of the semiconductor device of the first embodiment. FIG. 2 illustrates, as an example, a section of four transistors Tr and four capacitors Cp configuring four memory cells MC.

The semiconductor device of the present embodiment includes a substrate 101, a transistor 102, an inter layer dielectric 103, a plurality of contact plugs 104, an interconnect layer 105, an inter layer dielectric 106, an inter layer dielectric 107, and a plurality of via plugs 108. The transistor 102 includes a gate insulator 102a, a gate electrode 102b, a sidewall insulator 102c, a diffusion region 102d, and a diffusion region 102e.

The substrate 101 is, for example, a semiconductor substrate such as a silicon (Si) substrate. FIG. 2 illustrates an X direction and a Y direction which are parallel to a surface of the substrate 101 and perpendicular to each other, and a Z direction which is perpendicular to the surface of the substrate 101. In this description, a + Z direction is treated as an up direction, and a - Z direction is treated as a down direction. The - Z direction may or may not coincide with a direction of gravity.

The transistor 102 is formed on the substrate 101. Specifically, the gate insulator 102a and the gate electrode 102b are sequentially formed on the substrate 101, and the sidewall insulator 102c is formed on a side face of the gate electrode 102b. The diffusion regions 102d and 102e are formed in the substrate 101 so as to sandwich the gate electrode 102b, and function as source/drain regions of the transistor 102. The semiconductor device of the present embodiment includes a plurality of transistors 102, and FIG. 2 illustrates one of these transistors 102. These transistors 102 configure, for example, a peripheral circuit of a DRAM.

The inter layer dielectric 103 is formed on the substrate 101 to cover the transistors 102. Each of the contact plugs 104 is formed on the gate electrode 102b, the diffusion region 102d, or the diffusion region 102e in the inter layer dielectric 103. The interconnect layer 105 is formed on each contact plug 104 in the inter layer dielectric 103. FIG. 2 illustrates a plurality of interconnects involved in the interconnect layer 105.

The inter layer dielectric 106 is formed on the inter layer dielectric 103 and the interconnect layer 105. The inter layer dielectric 107 is formed on the inter layer dielectric 106. Each of the via plugs 108 is formed on the interconnect layer 105 in the inter layer dielectrics 106 and 107. In FIG. 2, each of the via plugs 108 penetrates the inter layer dielectrics 106 and 107.

Each of the capacitors Cp of the present embodiment includes a conductive layer 111, a dielectric layer 112, a conductive layer 113, and a conductive layer 114.

The conductive layer 111, the dielectric layer 112, the conductive layer 113, and the conductive layer 114 are sequentially formed on side and bottom faces of a concave portion formed in the inter layer dielectrics 106 and 107. Specifically, the conductive layer 111 is formed on side faces of the inter layer dielectrics 106 and 107 and an upper face of the interconnect layer 105 in the concave portion. The conductive layer 111 functions as one electrode of each of the capacitors Cp, and the conductive layers 113 and 114 function as the other electrode of each of the capacitors Cp. Each of the conductive layers 111, 113, and 114 is, for example, a semiconductor layer or a metal layer. The dielectric layer 112 is, for example, an SiO₂ film (silicon oxide film).

The semiconductor device of the present embodiment further includes a conductive layer 121, an inter layer dielectric 122, a plurality of via plugs 123, an interconnect layer 124, an inter layer dielectric 125, and an inter layer dielectric 126. The interconnect layer 124 includes an interconnects 124a and 124b. A stacked film including the inter layer dielectric 122, the interconnect layer 124, and the inter layer dielectric 126 is an example of a first film. The inter layer dielectric 122 is an example of a first insulator, and the inter layer dielectric 126 is an example of a second insulator.

The conductive layer 121 includes a plurality of conductive layer portions disposed on the plurality of capacitors Cp. In FIG. 2, the conductive layer 121 includes four conductive layer portions, and each conductive layer portion is disposed on the conductive layers 113 and 114 of the corresponding one capacitor Cp. Each of the conductive layer portions is disposed in the concave portion for the corresponding one capacitor Cp, and is disposed below a corresponding one transistor Tr. Each of the conductive layer portions functions as a source electrode or a drain electrode of the corresponding one transistor Tr.

The conductive layer 121 is, for example, an oxide conductive layer. The oxide conductive layer includes, for example, a metal element and oxygen. Examples of the oxide conductive layer include an InO-based conductive layer, a ZnO-based conductive layer, and a TiO-based conductive layer (In, O, Zn, and Ti representing indium, oxygen, zinc, and titanium, respectively). The conductive layer 121 in the present embodiment is, for example, an ITO (indium tin oxide) layer including In, Sn (tin), and O. On the other hand, the conductive layer 121 includes O, and may include at least one element selected from the group consisting of In, Ga (gallium), Zn, Sn, Ti, Ta (tantalum), W (tungsten), Mo (molybdenum), Al (aluminum), Mg (magnesium), Ca (calcium), and Mn (manganese).

The inter layer dielectric 122 is formed on the inter layer dielectric 107 to cover the capacitors Cp. Each of the via plugs 123 is formed on the corresponding one via plug 108 in the inter layer dielectric 122. The interconnect layer 124 and the inter layer dielectric 125 are formed on the inter layer dielectric 122. The interconnect 124a in the interconnect layer 124 is disposed on the corresponding one via plug 123, and the interconnect 124b in the interconnect layer 124 is also disposed on the corresponding one via plug 123. The interconnect 124a functions as a gate electrode of each of the transistors Tr illustrated in FIG. 2. The inter layer dielectric 126 is formed on the interconnect layer 124 and the inter layer dielectric 125. The inter layer dielectrics 122, 125, and 126 are, for example, SiO₂ films. The interconnect layer 124 is, for example, a metal layer such as a W layer.

Each of the transistors Tr of the present embodiment includes a semiconductor layer 131 and an insulator 132. Each of the transistors Tr of the present embodiment further includes the interconnect 124a in the interconnect layer 124, as a component of the transistor Tr. The insulator 132 is an example of a second film, and an example of a third insulator.

The semiconductor layer 131 is formed in a concave portion formed in the inter layer dielectric 122, the interconnect layer 124 (interconnect 124a) and the inter layer dielectric 126 via the insulator 132. In FIG. 2, the semiconductor layer 131 is formed on one conductive layer portion of the conductive layer 121, and is in contact with the conductive layer portion. Accordingly, the semiconductor layer 131 of each transistor Tr is electrically connected to the conductive layers 113 and 114 of the corresponding one capacitor Cp. The semiconductor layer 131 functions as a channel semiconductor layer of each transistor Tr. The semiconductor layer 131 is, for example, an oxide semiconductor layer. The oxide semiconductor layer includes a metal element and oxygen, for example. The semiconductor layer 131 of the present embodiment is an IGZO layer including In, Ga, Zn, and O, for example. On the other hand, the semiconductor layer 131 includes In and O, and may include at least one element selected from the group consisting of Ga, Zn, Sn, Al, and Si.

The insulator 132 is formed on the side face of the concave portion formed in the inter layer dielectric 122, the interconnect layer 124, and the inter layer dielectric 126, and is formed on the side face of the semiconductor layer 131 in the concave portion. The insulator 132 functions as a gate insulator of each transistor Tr. The insulator 132 is a stacked film including a SiO₂ film and a SiN film (silicon nitride film), for example.

In FIG. 2, the insulator 132 and the semiconductor layer 131 of each transistor Tr are formed in this order on the side face of the interconnect 124a. As described above, the interconnect 124a functions as a gate electrode of each transistor Tr. In addition, the interconnect 124a illustrated in FIG. 2 extends in the X direction, and functions as one word line WL for the four transistors Tr illustrated in FIG. 2. The interconnect 124a is electrically connected to the diffusion region 102d of the transistor 102 through the via plugs 123 and 108.

The semiconductor device of the present embodiment further includes a plurality of conductive pads 141, an inter layer dielectric 142, a via plug 143, an interconnect layer 144, an insulator 145, an insulator 146, and an inter layer dielectric 147. Each of the conductive pads 141 includes a conductive layer 141-1, a conductive layer 141-2, and a conductive layer 141-3. Furthermore, the interconnect layer 144 includes a plurality of interconnects 144a and interconnects 144b.

Each of the conductive pads 141 is formed on the semiconductor layer 131 of the corresponding one transistor Tr in the inter layer dielectric 142, and is in contact with such a semiconductor layer 131. Specifically, the conductive layers 141-1, 141-2, and 141-3 of each of the conductive pads 141 are formed in this order on the semiconductor layer 131. Each of the conductive pads 141 functions as a source electrode or a drain electrode of the corresponding one transistor Tr.

The conductive layer 141-1 is, for example, an oxide conductive layer. The oxide conductive layer includes a metal element or oxygen, for example. Examples of the oxide conductive layer include an InO-based conductive layer, a ZnO-based conductive layer, and a TiO-based conductive layer. The conductive layer 141-1 of the present embodiment is an ITO layer including In, Sn, and O, for example. On the other hand, the conductive layer 141-1 includes O, and may include at least one element selected from the group consisting of In, Ga, Zn, Sn, Ti, Ta, W, Mo, Al, Mg, Ca, and Mn. The conductive layer 141-2 is, for example, a TiN layer. The conductive layer 141-3 is, for example, a W layer.

The inter layer dielectric 142 is formed on the inter layer dielectric 126. The via plug 143 is formed on the interconnect 124b in the inter layer dielectrics 126 and 142. The interconnect 124b is electrically connected to the electrode 102b of the transistor 102 through the via plugs 123 and 108.

The interconnect layer 144, the insulator 145, and the insulator 146 are formed in the inter layer dielectric 147. In FIG. 2, each of the interconnects 144a in the interconnect layer 144 is formed on the corresponding one conductive pad 141. The four interconnects 144a illustrated in FIG. 2 extend in the Y direction, and function as four bit lines BL for the four transistors Tr, respectively. On the other hand, the interconnects 144b in the interconnect layer 144 are formed on the via plug 143. The interconnect layer 144 is, for example, a metal layer such as a W layer.

The insulator 145 is divided into a plurality of insulator portions, and each of the insulator portions in the insulator 145 is formed on one interconnect 144a or 144b. The insulator 145 is, for example, an SiO₂ film. The insulator 146 is divided into a plurality of insulator portions, and each of the insulator portions in the insulator 146 is formed on one insulator portion in the insulator 145. The insulator 146 is, for example, a SiN film. The inter layer dielectric 147 is formed on the inter layer dielectric 142.

The semiconductor device of the present embodiment further includes an inter layer dielectric 151, a via plug 152, an inter layer dielectric 153, and an interconnect layer 154. The inter layer dielectric 151 includes an insulator 151-1, an insulator 151-2, and an insulator 151-3.

The inter layer dielectric 151 is formed on the insulator 146 and the inter layer dielectric 147. Specifically, the insulator 151-1 is formed on the insulator 146 and the inter layer dielectric 147, the insulator 151-2 is formed on the insulator 151-1, and the insulator 151-3 is formed on the insulator 151-2. The insulator 151-1 is, for example, an SiO₂ film. The insulator 151-2 is, for example, a SiN film. The insulator 151-3 is, for example, an SiO₂ film.

The via plug 152 is formed on the interconnect 144b in the inter layer dielectrics 151, the insulator 146, and the insulator 145. The inter layer dielectric 153 is formed on the inter layer dielectric 151. The interconnect layer 154 is formed on the via plug 152 in the inter layer dielectric 153.

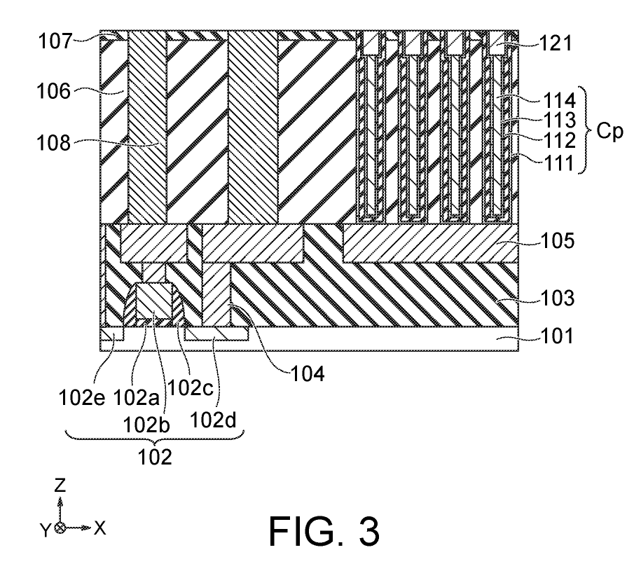

FIGS. 3 to 6 are cross-sectional views illustrating a method of manufacturing the semiconductor device of the first embodiment.

First, a transistor 102 is formed on a substrate 101 (see FIG. 3). Specifically, diffusion regions 102dand 102e are formed in the substrate 101, and a gate insulator 102a, a gate electrode 102b, and a sidewall insulator 102c are formed on the substrate 101.

Subsequently, an inter layer dielectric 103, a plurality of contact plugs 104, and an interconnect layer 105 are formed on the substrate 101 and the transistor 102 (see FIG. 3). Subsequently, an inter layer dielectric 106, an inter layer dielectric 107, and a plurality of via plugs 108 are formed on the inter layer dielectric 103 and the interconnect layer 105 (see FIG. 3).

Subsequently, a plurality of concave portions are formed in the inter layer dielectrics 106 and 107, and a plurality of capacitors Cp are formed in the concave portions (see FIG. 3). Each capacitor Cp is formed in such a manner that a conductive layer 111, a dielectric layer 112, a conductive layer 113, and a conductive layer 114 are sequentially formed in one concave portion. The conductive layer 111 is formed on the interconnect layer 105 in the concave portion. Thereafter, a plurality of conductive layer portions of the conductive layer 121 are also formed in the above-described plurality of concave portions. Each conductive layer portion is formed on the conductive layers 113 and 114 in one concave portion.

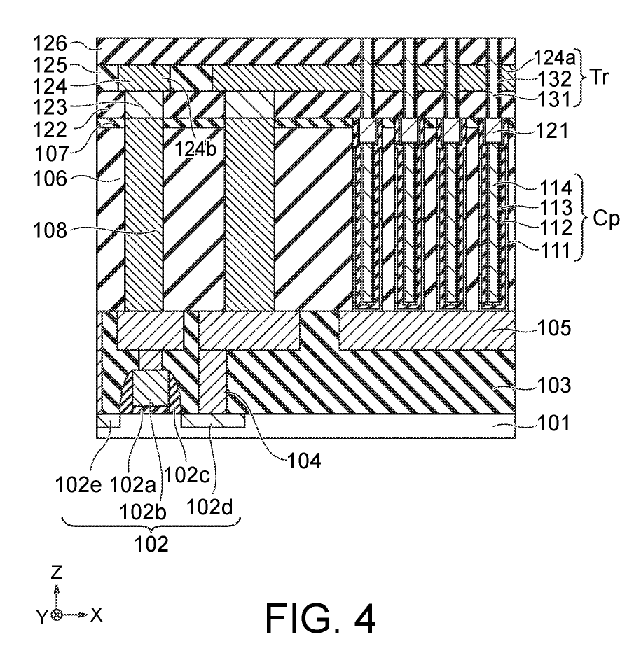

Subsequently, an inter layer dielectric 122 and a plurality of via plugs 123 are formed on the inter layer dielectric 107, the plurality of via plugs 108, and the conductive layer 121 (see FIG. 4). Subsequently, an interconnect layer 124 and an inter layer dielectric 125 are formed on the inter layer dielectric 122 and the plurality of via plugs 123 (see FIG. 4). The interconnect layer 124 is formed to include interconnects 124a and 124b. Subsequently, an inter layer dielectric 126 is formed on the interconnect layer 124 and the inter layer dielectric 125 (see FIG. 4).

Subsequently, a plurality of transistors Tr is formed in the inter layer dielectric 122, the interconnect layer 124 (interconnect 124a), and the inter layer dielectric 126 (see FIG. 4). Specifically, a plurality of concave portions are formed in the inter layer dielectric 122, the interconnect layer 124, and the inter layer dielectric 126, and an insulator 132 and a semiconductor layer 131 are sequentially formed in each of the concave portions. Thus, Each transistor Tr is formed include the semiconductor layer 131, the insulator 132, and the interconnect 124a. The semiconductor layer 131 of each transistor Tr is formed on one conductive layer portion of the conductive layer 121. As a result, the semiconductor layer 131 of each transistor Tr is electrically connected to the conductive layers 113 and 114 of the corresponding one capacitor Cp.

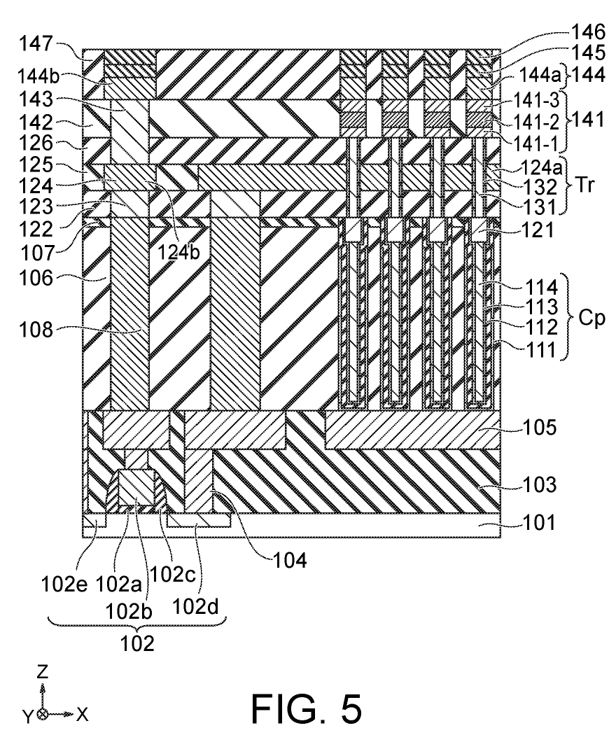

Subsequently, a plurality of conductive pads 141 and an inter layer dielectric 142 are formed on the inter layer dielectric 122 and the plurality of transistors Tr, and a via plug 143 is formed in the inter layer dielectrics 142 and 126 (see FIG. 5). Each of the conductive pads 141 is formed to include conductive layers 141-1, 141-2, and 141-3 which are sequentially formed on the semiconductor layer 131 of the corresponding one transistor Tr. The via plug 143 is formed on the interconnect 124b of the interconnect layer 124.

Subsequently, an interconnect layer 144, an insulator 145, an insulator 146, and an inter layer dielectric 147 are formed on the plurality of conductive pads 141, the inter layer dielectric 142, and the via plug 143 (see FIG. 5). The interconnect layer 144 is formed to include a plurality of interconnects 144a on the plurality of conductive pads 141 and an interconnect 144b on the via plug 143. The insulators 145 and 146 are sequentially formed on the interconnect layer 144. Each of the insulators 145 and 146 is divided into a plurality of insulator portions, similarly to the interconnects 144a and 144b in the interconnect layer 144.

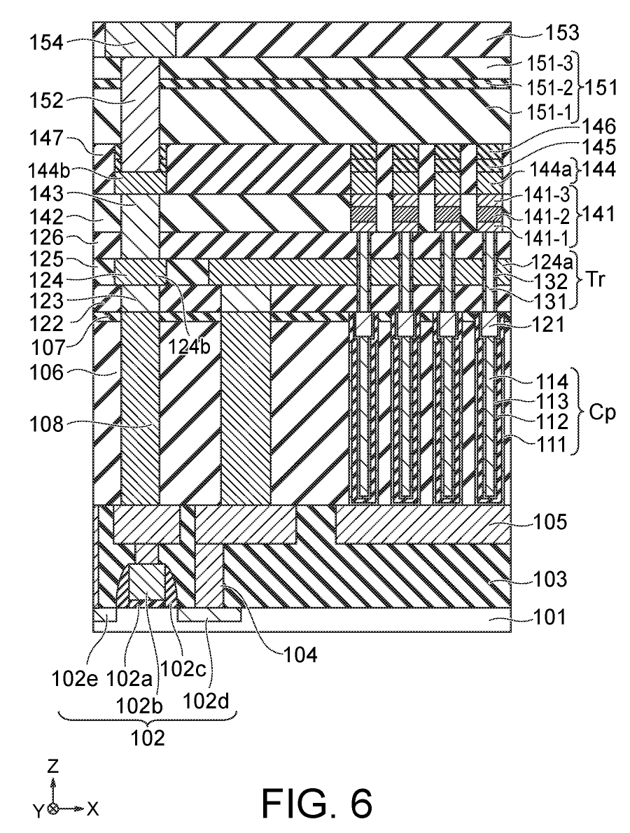

Subsequently, an inter layer dielectric 151 is formed on the insulator 146 and the inter layer dielectric 147, and a via plug 152 is formed in the inter layer dielectric 151, the insulator 146, and the insulator 145 (see FIG. 6). The inter layer dielectric 151 is formed to include insulators 151-1, 151-2, and 151-3 which are sequentially formed on the insulator 146 and the inter layer dielectric 147. The via plug 152 is formed on the interconnect 144b.

Subsequently, an inter layer dielectric 153 and an interconnect layer 154 are formed on the inter layer dielectric 151 and the via plug 152 (see FIG. 6). The interconnect layer 154 is formed on the via plug 152. In this manner, the semiconductor device of the present embodiment is manufactured.

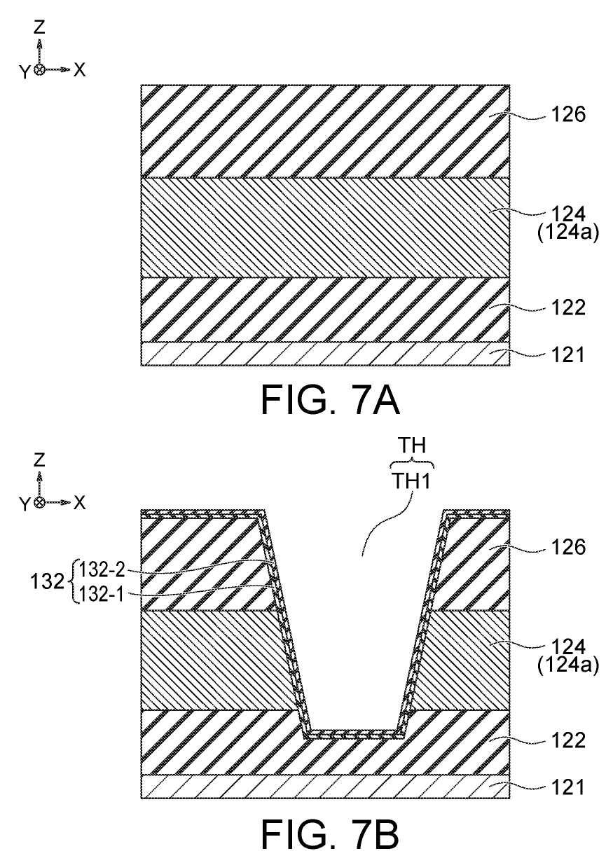

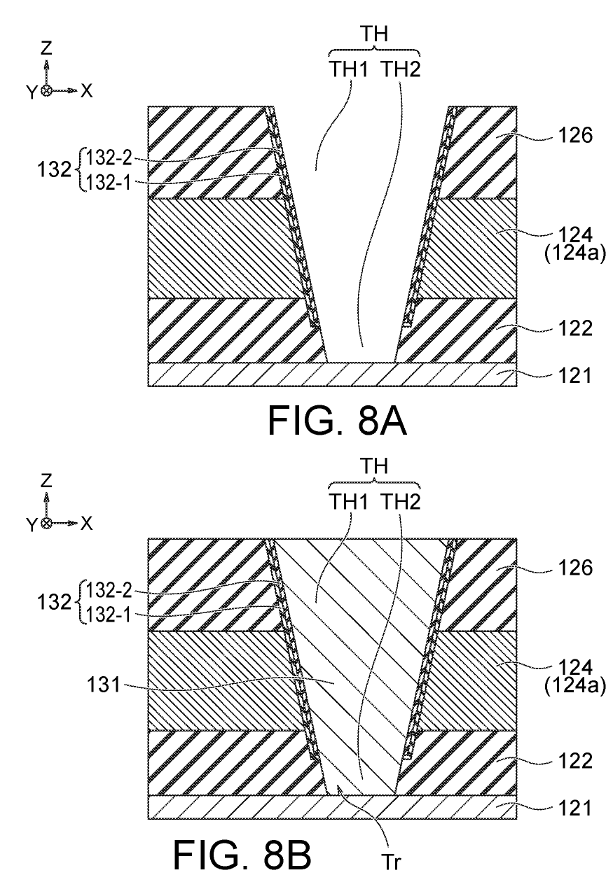

FIGS. 7A-8B are cross-sectional views illustrating the method of manufacturing the semiconductor device of the first embodiment. FIGS. 7A-8B mainly illustrate details of the process illustrated in FIG. 4, and more specifically, illustrate details of a process of forming one transistor Tr.

First, a conductive layer 121 is formed, and an inter layer dielectric 122, an interconnect layer 124 (interconnect 124a), and an inter layer dielectric 126 are sequentially formed on the conductive layer 121 (see FIG. 7A). A stacked film including the inter layer dielectric 122, the interconnect layer 124, and the inter layer dielectric 126 is an example of a first film. The inter layer dielectric 122 is an example of a first insulator, and the inter layer dielectric 126 is an example of a second insulator.

Subsequently, an upper hole TH1, which is a portion of a transistor hole TH, is formed in the inter layer dielectric 126, the interconnect layer 124, and the inter layer dielectric 122 by reactive ion etching (RIE) (see FIG. 7B). The upper hole TH1 of the present embodiment is formed to penetrate the inter layer dielectric 126 and the interconnect layer 124 but not to penetrate the inter layer dielectric 122. The transistor hole TH is an example of a concave portion. Moreover, the upper hole TH1 is an example of a first portion of the concave portion.

Subsequently, an insulator 132 is formed on the inter layer dielectric 126, the interconnect layer 124, and the inter layer dielectric 122 (see FIG. 7B). As a result, the insulator 132 is formed on side faces of the inter layer dielectric 126, the interconnect layer 124, and the inter layer dielectric 122 in the upper hole TH1 (side faces of the upper hole TH1), an upper face of the inter layer dielectric 122 in the upper hole TH1 (a bottom face of the upper hole TH1), and an upper face of the inter layer dielectric 126 outside the upper hole TH1. The insulator 132 is an example of a second film, and an example of a third insulator.

The insulator 132 of the present embodiment is formed to include an insulator 132-1 formed on the inter layer dielectric 126, the interconnect layer 124, and the inter layer dielectric 122, and an insulator 132-2 formed on the insulator 132-1. The insulator 132-1 is, for example, an SiO₂ film. The insulator 132-2 is, for example, a SiN film. The insulator 132-1 is an example of a fourth insulator, and the insulator 132-2 is an example of a fifth insulator.

Subsequently, the insulator 132 and the inter layer dielectric 122 is etched by RIE (see FIG. 8A). As a result, the insulator 132 is removed from the upper face of the inter layer dielectric 122 in the upper hole TH1 and the upper face of the inter layer dielectric 126 outside the upper hole TH1. Furthermore, the inter layer dielectric 122 below the upper hole TH1 is removed, and a lower hole TH2, which is a remaining portion of the transistor hole TH, is formed below the upper hole TH1 in the inter layer dielectric 122. The lower hole TH2 of the present embodiment is formed to penetrate the inter layer dielectric 122. Therefore, the surface (upper face) of the conductive layer 121 is exposed in the lower hole TH2. FIG. 8A illustrates the conductive layer 121 exposed from the inter layer dielectric 122 in the transistor hole TH. The lower hole TH2 is an example of a second portion of the concave portion.

After the process in FIG. 8A, the insulator 132 remains on the side faces of the inter layer dielectric 126 in the transistor hole TH, the side faces of the interconnect 124a in the transistor hole TH, and a portion of the side faces of the inter layer dielectric 122 in the transistor hole TH. In the process in FIG. 8A, not only the inter layer dielectric 122 below the upper hole TH1 is removed, but also a portion of the inter layer dielectric 126 may be etched from the upper face of the inter layer dielectric 126 outside the upper hole TH1. In this case, the inter layer dielectric 126 is thinned by etching.

Subsequently, the semiconductor layer 131 is formed in the transistor hole TH (see FIG. 8B). As a result, a transistor Tr including the semiconductor layer 131, the insulator 132, and the interconnect 124a is formed. The semiconductor layer 131 is formed on the side face of the interconnect 124a in the transistor hole TH via the insulator 132. The semiconductor layer 131 is formed in the transistor hole TH to contact the surface of the conductive layer 121.

Next, a description will be given with respect to a comparison between the method of manufacturing the semiconductor device of the first embodiment and a method of manufacturing a semiconductor device of a comparative example of the first embodiment.

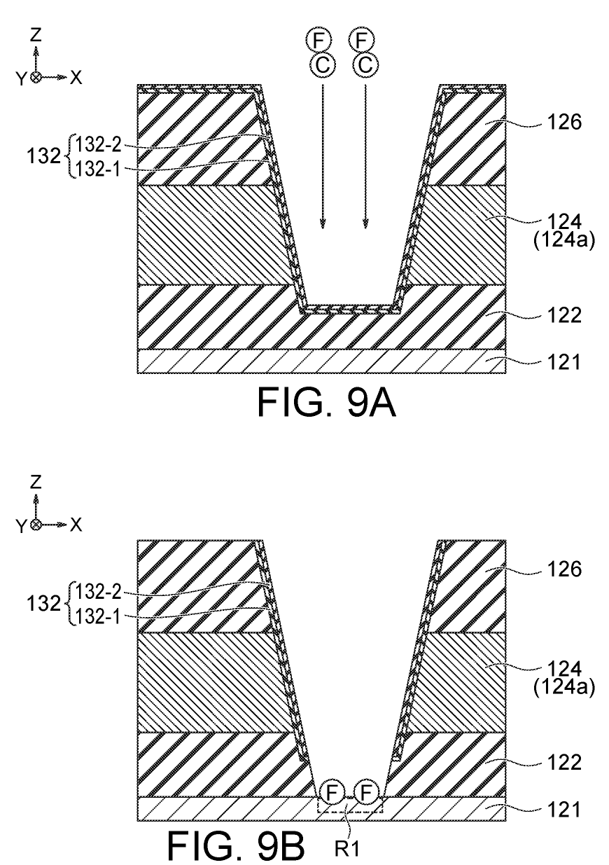

FIGS. 9A and 9B are cross-sectional views illustrating a method of manufacturing a semiconductor device of a comparative example of the first embodiment. In the comparative example, the process in FIG. 8A is performed as follows.

In the comparative example, the insulator 132 and the inter layer dielectric 122 are etched by RIE using an etching gas including F (fluorine) (see FIG. 9A). As a result, the lower hole TH2 is formed below the upper hole TH1 (see FIG. 9B). The etching gas is, for example, a CF-based gas including C (carbon) and F.

In a process in FIG. 9A, F atoms derived from the etching gas may react with the conductive layer 121 exposed from the inter layer dielectric 122. For example, In (indium) atoms in the conductive layer 121 react with F (fluorine) atoms to produce indium fluoride. As a result, a region R1 having a high concentration of F atoms is formed in the conductive layer 121 near the bottom face of the transistor hole TH, as illustrated in FIG. 9B. This may increase in electrical resistance of the conductive layer 121.

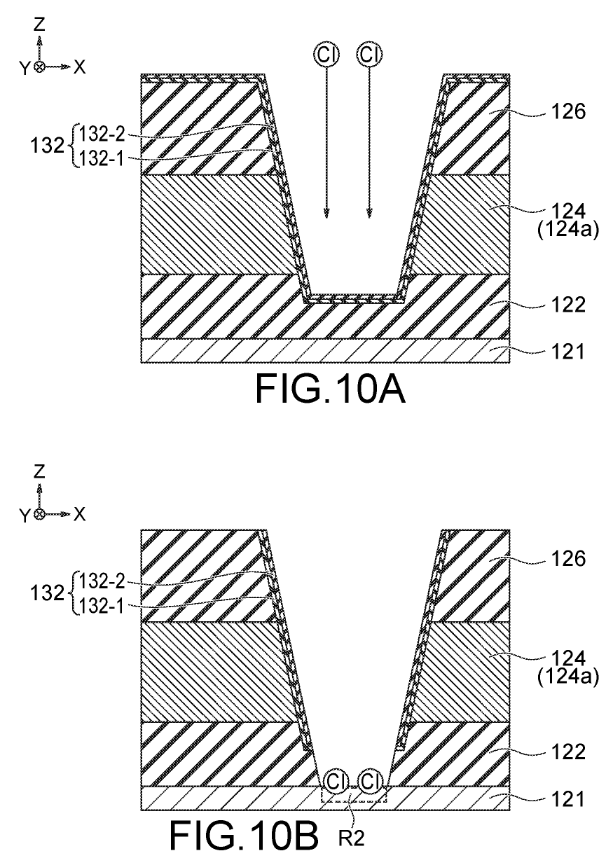

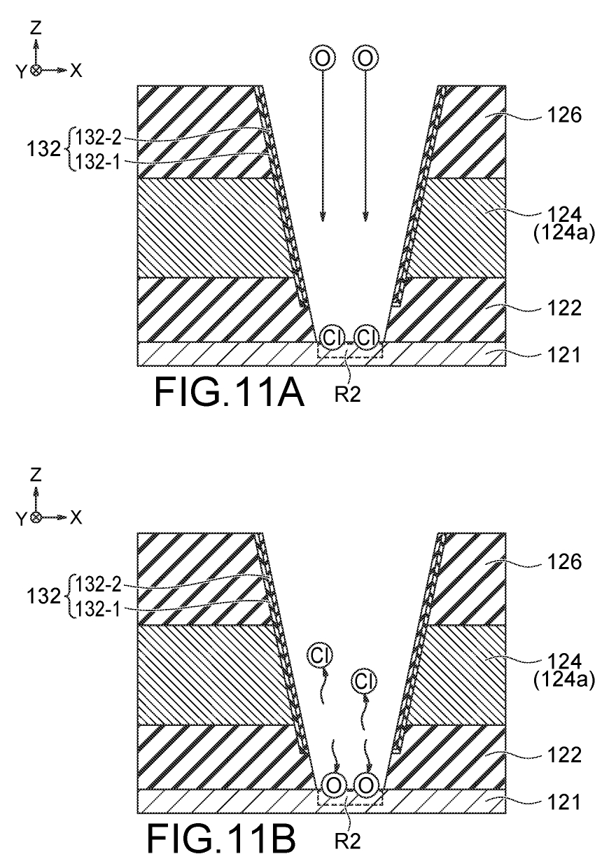

FIGS. 10A-11B are cross-sectional views illustrating the method of manufacturing the semiconductor device of the first embodiment. In the present embodiment, the process in FIG. 8A is performed as follows.

In the present embodiment, the insulator 132 and the inter layer dielectric 122 are etched by RIE using an etching gas including Cl (chlorine) (see FIG. 10A). As a result, the lower hole TH2 is formed below the upper hole TH1 (see FIG. 10B). The etching gas is, for example, a Cl₂ gas (chlorine gas). In the present embodiment, the insulator 132 and the inter layer dielectric 122 are etched by plasma generated from the Cl₂ gas. The etching gas is an example of a first gas. In addition, Cl (chlorine) is an example of a first element.

In a process in FIG. 10A, Cl atoms derived from the etching gas may react with the conductive layer 121 exposed from the inter layer dielectric 122. For example, In (indium) atoms in the conductive layer 121 react with Cl (chlorine) atoms to produce indium chloride in the conductive layer 121. As a result, a region R2 having a high concentration of Cl atoms is formed in the conductive layer 121 near the bottom face of the transistor hole TH, as illustrated in FIG. 10B. This may increase in electrical resistance of the conductive layer 121.

Therefore, in the present embodiment, the surface of the conductive layer 121 exposed in the transistor hole TH is oxidized (see FIG. 11A). As a result, the indium chloride in the conductive layer 121 reacts with O (oxygen) atoms derived from oxidation and converts back into indium oxide. This makes it possible to release Cl atoms of the indium chloride from the conductive layer 121, thereby making it possible to reduce a concentration of Cl in the region R2 (see FIG. 11B). The present embodiment makes it possible to oxidize the surface of the conductive layer 121, and to reduce the electrical resistance of the conductive layer 121 again. In the present embodiment, after the conductive layer 121 is oxidized, the semiconductor layer 131 is formed in the transistor hole TH (see FIG. 8B). The semiconductor layer 131 is formed on the conductive layer 121 to contact the oxidized surface of the conductive layer 121.

The conductive layer 121 is oxidized by plasma oxidation at a temperature within a range of 50°C to 400°C, for example. The use of the plasma oxidation has advantages that the conductive layer 121 can be oxidized at a low temperature, and that the etching in FIG. 10A and the oxidation in FIG. 11A can be performed using the same plasma processing apparatus. When the etching is performed at a room temperature and the oxidation is performed at a low temperature, the etching and the oxidation are easily performed in the same apparatus. However, the conductive layer 121 may be oxidized by oxidation (for example, thermal oxidation) other than the plasma oxidation, and may be oxidized at a temperature outside the range of 50°C to 400°C. For example, when the conductive layer 121 is oxidized at a high temperature, the conductive layer 121 can be oxidized at a short time.

Regarding binding energy between the In atom and other atoms, In-F binding energy is 516 kJ/Mmol, In-O binding energy is 346 kJ/Mmol, and In-Cl binding energy is 211 kJ/Mmol. In other words, indium fluoride is stable, whereas indium chloride can easily become indium oxide. Accordingly, the indium fluoride is difficult to convert back into indium oxide, but the indium chloride easily converts back into indium oxide. Therefore, in the present embodiment, the insulator 132 and the inter layer dielectric 122 are etched using the etching gas including Cl instead of F. This makes it possible to easily remove Cl atoms from the conductive layer 121, and to return the electrical resistance of the conductive layer 121 to a low level due to the removal of the Cl atoms.

When the step shown in FIG. 10A is performed, the Cl₂ gas may be used during only a part of the period of the RIE, instead of all the period of the RIE. For example, at least the insulator 132 of the insulator 132 and the inter layer dielectric 122 may be etched with a CF₄ gas during a first period of the RIE, and at least the inter layer dielectric 122 of the insulator 132 and the inter layer dielectric 122 may be etched with the Cl₂ gas during a second period of the RIE. In this case, the lower hole TH2 is formed below the upper hole TH1 by performing the RIE of the first period and then performing the RIE of the second period. In general, the etching rate of the CF₄ gas is larger than the etching rate of the Cl₂ gas, which makes it possible to shorten the etching time. The RIE of the first period may be performed using a gas other than the CF₄ gas as the CF-based gas. The RIE of the second period may be performed using a gas other than the Cl₂ gas as the gas including Cl.

Furthermore, when the step of forming the upper hole TH1 shown in FIG. 7A is performed, the CF₄ gas may be used. For example, the CF₄ gas may be used in the step of forming the upper hole TH1 shown in FIG. 7A, and the Cl₂ gas may be used in the step of forming the lower hole TH2 shown in FIG. 8A or 10A. Alternatively, when the step of forming the upper hole TH1 shown in FIG. 7A is performed, the CF₄ gas may be used during only a part of the period of the RIE, instead of all the period of the RIE.

Hereinafter, the processes illustrated in FIGS. 10A-11B will be described in more detail.

The etching gas of the present embodiment may be any gas other than the Cl₂ gas as long as including Cl. For example, the etching gas of the present embodiment may be HCl gas, BCl₃ gas, or SiCl₄ gas (here, "H", "B", and "Si" representing hydrogen, boron, and silicon, respectively). This makes it possible to obtain the same effect as in a case of using Cl₂ gas.

The etching gas of the present embodiment is preferably a gas including Cl, and is preferably a gas not including F. Molecules in the etching gas of the present embodiment are preferably not only molecules including Cl atoms, for example, Cl₂ molecules, HCl molecules, BCl₃ molecules, and SiCl₄ molecules, but also molecules not including F atoms. In addition, the etching gas of the present embodiment may include a halogen element (for example, Br (bromine)) other than F and Cl. From the viewpoint of the above-described binding energy, the element included in the etching gas of the present embodiment is preferably an element whose binding energy with indium is smaller than the binding energy between indium and oxygen. Regarding such a relationship, when a metal element to be oxidized is an element other than indium, the indium in the relationship is replaced with such a metal element.

The conductive layer 121 may be oxidized such that Cl atoms are completely removed from the conductive layer 121, or may be oxidized such that Cl atoms are not completely removed from the conductive layer 121. In the latter case, the semiconductor device of the present embodiment includes Cl atoms in the conductive layer 121. However, the conductive layer 121 is preferably oxidized such that Cl atoms are removed from the conductive layer 121 as many as possible.

In the present embodiment, the semiconductor layer 131 is an IGZO layer, and the conductive layer 121 and the conductive layer 141-1 are ITO layers. When the semiconductor layer 131 is an IGZO layer, if the conductive layer 121 in contact with the semiconductor layer 131 is a metal layer such as a W layer, there is high concern that metal atoms (for example, W atoms) in the conductive layer 121 diffuse into the semiconductor layer 131, or that O atoms in the semiconductor layer 131 diffuse into the conductive layer 121. The present embodiment makes it possible to prevent such diffusion using the conductive layer 121 as an ITO layer. The same applies to the conductive layer 141-1.

When the conductive layer 121 is an ITO layer, as described above, there is a problem in that the electrical resistance of the conductive layer 121 increases due to fluorination or chlorination of the conductive layer 121. The present embodiment makes it possible to solve the problem as described above, by forming the lower hole TH 2 using the etching gas including Cl and then oxidizing the conductive layer 121.

In the present embodiment, when the lower hole TH2 is formed by the RIE, the insulator 132 and the inter layer dielectric 122 are etched by the plasma generated from the Cl₂ gas. Accordingly, when the oxidation of the conductive layer 121 is performed by the plasma oxidation, the RIE and the oxidation can be performed in-situ in the same RIE chamber. This makes it possible to eliminate the need to carry out the substrate 101 from the RIE chamber during the RIE and the oxidation, and to reduce the time and effort required for the RIE and the oxidation. Furthermore, since the substrate 101 including Cl atoms in the conductive layer 121 due to RIE does not need to be placed in a front opening unified pod (FOUP) for transportation, contamination of the FOUP due to Cl atoms can be prevented. Since the chlorine gas is a corrosive gas, it is preferable to prevent such FOUP contamination.

On the other hand, the RIE and the oxidation may be performed by different apparatuses. For example, the RIE may be performed in an RIE chamber of an RIE apparatus, and the oxidation may be performed by an oxidation apparatus such as an asher. In this case, the oxidation may be performed by a method other than the plasma oxidation, or may be performed by thermal oxidation, for example. The oxidation may be first performed in the RIE chamber and then in the asher.

As described above, according to the present embodiment, the lower hole TH2 is formed using the etching gas including Cl, and then the surface of the conductive layer 121 is oxidized. This makes it possible to remove Cl atoms from the conductive layer 121, and to reduce the electrical resistance of the conductive layer 121 due to the removal of the Cl atoms. In this manner, the present embodiment makes it possible to suitably etch the film (for example, the insulator 132) on the conductive layer 121.

### Second Embodiment

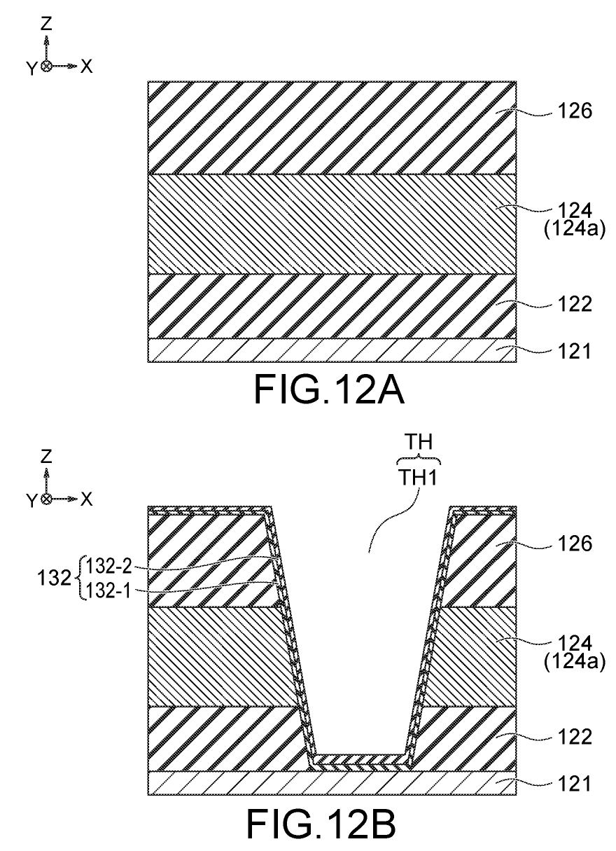

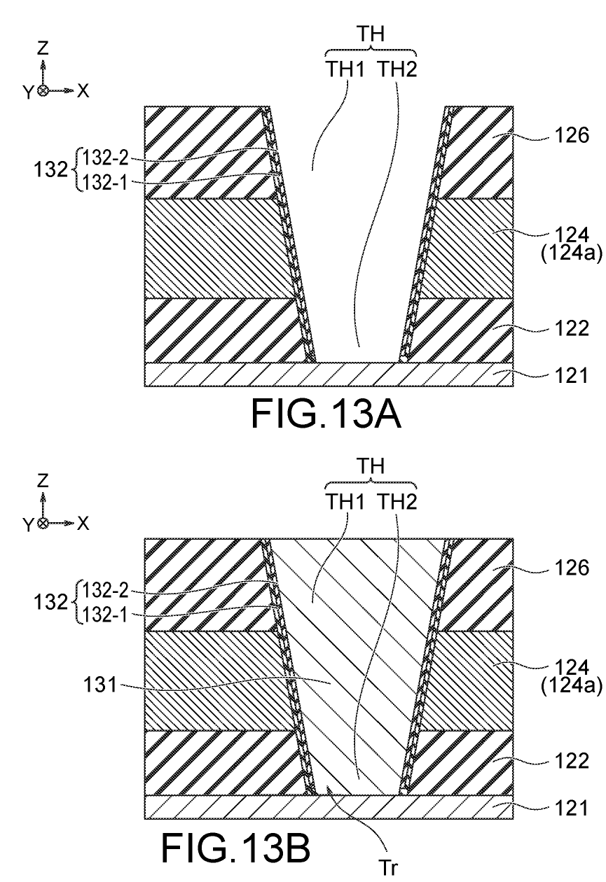

FIGS. 12A-13B are cross-sectional views illustrating a method of manufacturing a semiconductor device of a second embodiment. In the present embodiment, processes illustrated in FIGS. 12A-13B are performed instead of the processes illustrated in FIGS. 7A-8B. In the present embodiment, points common to the first embodiment will not be described.

First, a conductive layer 121 is formed, and an inter layer dielectric 122, an interconnect layer 124 (interconnect 124a), and an inter layer dielectric 126 are sequentially formed on the conductive layer 121 (see FIG. 12A).

Subsequently, an upper hole TH1, which is a portion of a transistor hole TH, is formed in the inter layer dielectric 126, the interconnect layer 124, and the inter layer dielectric 122 by RIE (see FIG. 12B). The upper hole TH1 of the first embodiment is formed to penetrate the inter layer dielectric 126 and the interconnect layer 124 but not to penetrate the inter layer dielectric 122, whereas the upper hole TH1 of the second embodiment is formed to formed to penetrate the inter layer dielectric 126, the interconnect layer 124, and the inter layer dielectric 122.

Subsequently, an insulator 132 is formed on the inter layer dielectric 126, the interconnect layer 124, and the inter layer dielectric 122 (see FIG. 12B). As a result, the insulator 132 is formed on side faces of the inter layer dielectric 126, the interconnect layer 124, and the inter layer dielectric 122 in the upper hole TH1 (side faces of the upper hole TH1), an upper face of the conductive layer 121 in the upper hole TH1 (a bottom face of the upper hole TH1), and an upper face of the inter layer dielectric 126 outside the upper hole TH1. The insulator 132 is formed to include an insulator 132-1 and an insulator 132-2.

Subsequently, the insulator 132 is etched by RIE (see FIG. 13A). As a result, the insulator 132 is removed from the upper face of the conductive layer 121 in the upper hole TH1 and the upper face of the inter layer dielectric 126 outside the upper hole TH1. Thus, a lower hole TH2, which is a remaining portion of the transistor hole TH, is formed below the upper hole TH1 in the inter layer dielectric 122. The lower hole TH2 of the present embodiment is formed to penetrate the insulator 132. Therefore, the surface (upper face) of the conductive layer 121 is exposed in the lower hole TH2. FIG. 13A illustrates the conductive layer 121 exposed from the inter layer dielectric 122 in the transistor hole TH.

After the process in FIG. 13A, the insulator 132 remains on the side faces of the inter layer dielectric 126 in the transistor hole TH, the side faces of the interconnect 124a in the transistor hole TH, and the side faces of the inter layer dielectric 122 in the transistor hole TH. In the process in FIG. 13A, when the insulator 132 below the upper hole TH1 is removed, a portion of the inter layer dielectric 126 may be etched from the upper face of the inter layer dielectric 126 outside the upper hole TH1. In this case, the inter layer dielectric 126 is thinned by etching.

Subsequently, a semiconductor layer 131 is formed in the transistor hole TH (see FIG. 13B). As a result, a transistor Tr including the semiconductor layer 131, the insulator 132, and the interconnect 124a is formed. The semiconductor layer 131 is formed on the side face of the interconnect 124a in the transistor hole TH via the insulator 132.

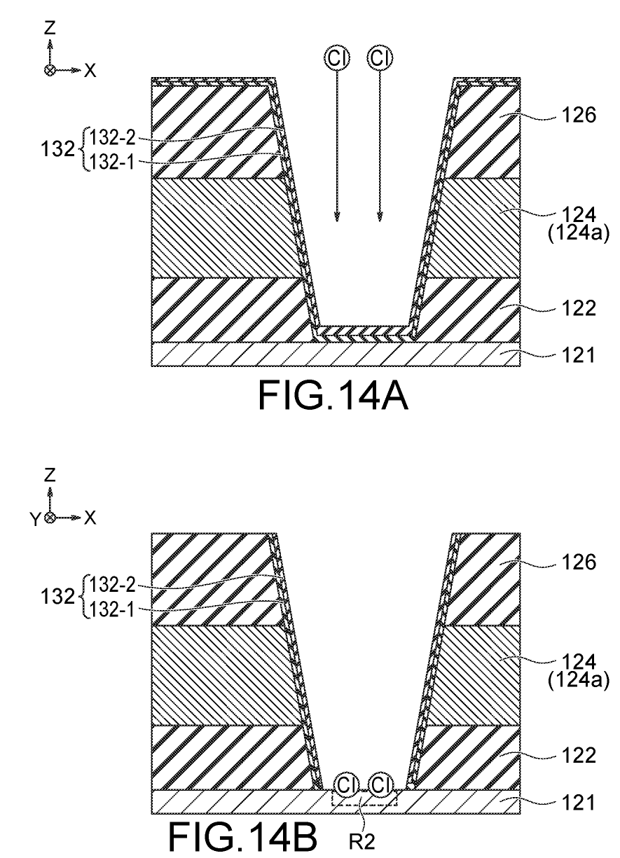

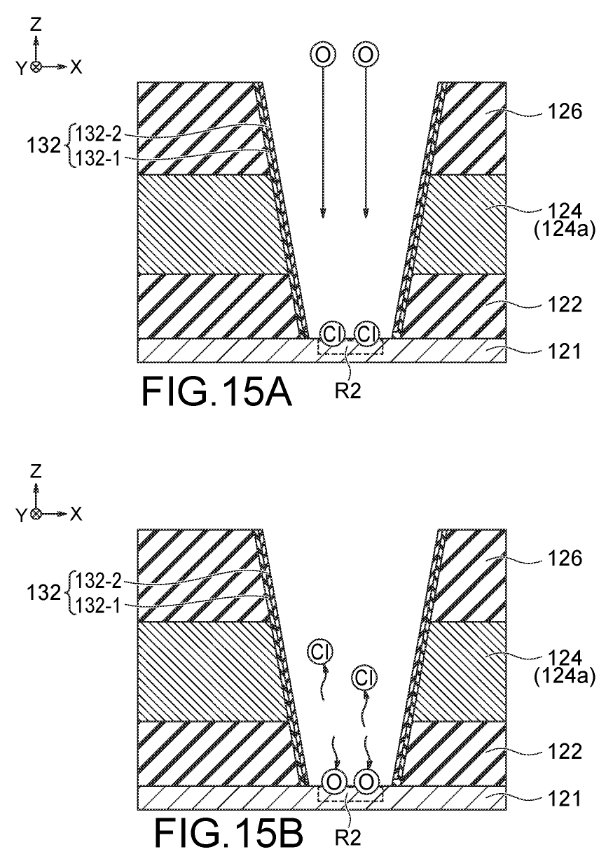

FIGS. 14A-15B are cross-sectional views illustrating a method of manufacturing the semiconductor device of the second embodiment. In the present embodiment, processes illustrated in FIGS. 14A-15B are performed instead of the processes illustrated in FIGS. 10A-11B. In the present embodiment, points common to the first embodiment will not be described.

In the present embodiment, the insulator 132 is etched by RIE using an etching gas including Cl (chlorine) (see FIG. 14A). As a result, the lower hole TH2 is formed below the upper hole TH1 (see FIG. 14B). The etching gas is, for example, a Cl₂ gas. FIG. 14B illustrates a region R2 having a high concentration of Cl atoms formed in the conductive layer 121, similarly to FIG. 10B.

Subsequently, the surface of the conductive layer 121 exposed in the transistor hole TH is oxidized (see FIG. 15A). As a result, indium chloride in the conductive layer 121 reacts with O (oxygen) atoms derived from oxidation and converts back into indium oxide. This makes it possible to release Cl atoms of the indium chloride from the conductive layer 121, thereby making it possible to reduce the concentration of Cl in the region R2 (see FIG. 15B). In the present embodiment, after the conductive layer 121 is oxidized, the semiconductor layer 131 is formed in the transistor hole TH (see FIG. 13B).

When the step shown in FIG. 14A is performed, the Cl₂ gas may be used during only a part of the period of the RIE, instead of all the period of the RIE. For example, at least the insulator 132 of the insulator 132 and the inter layer dielectric 122 may be etched with a CF₄ gas during a first period of the RIE, and at least the inter layer dielectric 122 of the insulator 132 and the inter layer dielectric 122 may be etched with the Cl₂ gas during a second period of the RIE. In general, the etching rate of the CF₄ gas is larger than the etching rate of the Cl₂ gas, which makes it possible to shorten the etching time. The RIE of the first period may be performed using a gas other than the CF₄ gas as the CF-based gas. The RIE of the second period may be performed using a gas other than the Cl₂ gas as the gas including Cl.

Here, the present embodiment will be compared to the first embodiment.

In the first embodiment, the upper hole TH1 is formed not to penetrate the inter layer dielectric 122. This makes it possible to prevent the In atoms in the conductive layer 121 from reacting with Cl atoms when the upper hole TH1 is formed.

On the other hand, the upper hole TH1 of the present embodiment is formed to penetrate the inter layer dielectric 122. This makes it possible to prevent the inter layer dielectric 126 from being significantly thinned by etching when the lower hole TH2 is formed.

The present embodiment makes it possible to suitably etch the film (for example, the insulator 132) on the conductive layer 121, similarly to the first embodiment.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a conductive layer including a metal element and oxygen;
forming a first film on the conductive layer;
forming a concave portion in the first film;
forming a second film in the concave portion;
etching the second film in the concave portion using a first gas including Cl (chloride) to expose a surface of the conductive layer in the concave portion;
oxidizing the surface of the conductive layer exposed in the concave portion; and
forming a semiconductor layer in the concave portion such that the semiconductor layer contacts the oxidized surface of the conductive layer.

2. The method of claim 1, wherein the conductive layer is an oxide conductive layer.

3. The method of claim 1, wherein the metal element is In (indium), Sn (tin), Zn (zinc) or Ti (titanium).

4. The method of claim 1, wherein the conductive layer is an ITO (indium tin oxide) layer.

5. The method of claim 1, wherein the semiconductor layer is an oxide semiconductor layer.

6. The method of claim 1, wherein the semiconductor layer includes In (indium), Ga (gallium) and Zn (zinc).

7. The method of claim 1, wherein the semiconductor layer is an IGZO layer.

8. The method of claim 1, wherein
the first film includes a first insulator formed on the conductive layer, an interconnect layer formed on the first insulator, and a second insulator formed on the interconnect layer,
the second film includes a third insulator, and
the semiconductor layer is formed on a side face of the interconnect layer via the third insulator in the concave portion.

9. The method of claim 8, wherein the third insulator includes a fourth insulator including oxygen, and a fifth insulator including nitrogen.

10. The method of claim 1, further comprising:
forming a first portion of the concave portion in the first film, when forming the concave portion in the first film;
forming the second film on a side face and a bottom face of the first portion of the concave portion, when forming the second film in the concave portion; and
removing the second film formed on the bottom face of the first portion of the concave portion to form a second portion of the concave portion below the first portion of the concave portion, when etching the second film in the concave portion.

11. The method of claim 10, wherein
the first portion of the concave portion is formed so as not to penetrate the first film, and
the second portion of the concave portion is formed so as to penetrate the second film and the first film.

12. The method of claim 10, wherein
the first portion of the concave portion is formed so as to penetrate the first film, and
the second portion of the concave portion is formed so as to penetrate the second film.

13. The method of claim 1, wherein the second film in the concave portion is etched by plasma generated from the first gas.

14. The method of claim 1, wherein the first gas includes a Cl₂ gas, an HCl gas, a BCl₃ gas or a SiCl₄ gas where H, B and Si represent hydrogen, boron and silicon, respectively.

15. The method of claim 1, wherein the first gas does not include F (fluorine).

16. The method of claim 1, wherein the oxidation is performed by plasma oxidation or thermal oxidation.

17. The method of claim 1, wherein the oxidation is performed at a temperature of 50°C to 400°C.

18. A method of manufacturing a semiconductor device, comprising:
forming a conductive layer including a metal element and oxygen;
forming a film on the conductive layer;
etching the film using a first gas including a first element to expose a surface of the conductive layer from the film; and
oxidizing the surface of the conductive layer exposed from the film,
wherein binding energy between the metal element and the first element is smaller than binding energy between the metal element and oxygen.

19. The method of claim 18, wherein the metal element is In (indium), and the first element is Cl (chlorine).

20. The method of claim 18, further comprising forming a semiconductor layer on the oxidized surface of the conductive layer.
